(19) United States
(12) Patent Application Publication
(10) Pub. No.: US 2006/0202315 A1
(43) Pub. Date: Sep. 14, 2006

(54) Microelectronic devices having conductive complementary structures and methods of manufacturing microelectronic devices have conductive complementary structures

(75) Inventors: Peter A. Benson, Boise, ID (US); William M. Hiatt, Eagle, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/418,362

(22) Filed: May 4, 2006

Related U.S. Application Data
(62) Division of application No. 10/713,626, filed on Nov. 13, 2003.

(51) Int. Cl. H01L 23/02

(52) U.S. Cl. 257/678

(57) ABSTRACT

Microelectronic devices, microfeature workpieces, and methods of forming and stacking the microelectronic devices and the microfeature workpieces. In one embodiment, a microfeature workpiece includes a plurality of first microelectronic dies. The individual first dies have an integrated circuit, a plurality of pads electrically coupled to the integrated circuit, and a plurality of first conductive mating structures at least proximate to corresponding pads. The first conductive mating structures project away from the first dies and are configured to interconnect with corresponding complementary second conductive mating structures on second dies which are to be mounted to corresponding first dies.

### CROSS-REFERENCE TO RELATED APPLICATION(S)

This application is related to co-pending U.S. application Ser. No. ______ (Attorney Docket No. 10829.8742US) filed on ______, which is incorporated herein by reference in its entirety.

### TECHNICAL FIELD

The present invention is related to microelectronic devices having conductive complementary structures and methods of manufacturing microelectronic devices having conductive complementary structures.

### BACKGROUND

A conventional die-level packaged microelectronic device includes a microelectronic die, an interposer substrate or lead frame attached to the die, and a molded casing around the die. The microelectronic die generally includes an integrated circuit and a plurality of bond-pads coupled to the integrated circuit. The bond-pads are coupled to terminals on the interposer substrate or lead frame and serve as external electrical contacts on the die. In addition to the terminals, the interposer substrate can also include a dielectric material, a plurality of conductive traces in the dielectric material, and a plurality of ball-pads coupled to the terminals by corresponding conductive traces. A plurality of solder balls can be attached to the ball-pads in one-to-one correspondence to define a “ball-grid array.” Packaged microelectronic devices with ball-grid arrays are generally higher grade packages having lower profiles and higher pin counts than conventional packages using lead frames.

A typical process for packaging a singulated die to form a die-level package includes (a) attaching an individual singulated die to an interposer substrate, (b) wire-bonding the bond-pads of the die to the terminals of the interposer substrate, and (c) encapsulating the die with a suitable molding compound. Mounting individual dies to interposer substrates or lead frames in the foregoing manner can be a time-consuming and expensive process. In addition, forming robust wire-bonds that can withstand the forces involved in the molding process becomes more difficult as the demand for smaller packages increases. Moreover, the process of attaching individual dies to interposer substrates or lead frames may damage the bare dies. These difficulties have made the packaging process a significant factor in the production of microelectronic devices.

Another process for packaging microelectronic devices is wafer-level packaging. In this process, a plurality of microelectronic dies are formed on a wafer and a redistribution layer is formed on top of the dies. The redistribution layer can include a dielectric layer and a plurality of exposed ball-pads forming arrays on the dielectric layer. Each ball-pad array is typically arranged over a corresponding die, and a plurality of conductive traces couple the ball-pads in each array to corresponding bond-pads on the die. After forming the redistribution layer on the wafer, discrete masses of solder paste are deposited onto the individual ball-pads. The solder paste is then reflowed to form small solder balls or “solder bumps” on the ball-pads. After forming the solder balls, the wafer is singulated to separate the individual microelectronic devices from each other.

Wafer-level packaging is a promising development for increasing efficiency and reducing the cost of microelectronic devices. By “pre-packaging” individual dies with a redistribution layer before cutting the wafers to singulate the dies, sophisticated semiconductor processing techniques can be used to form smaller arrays of solder balls. Additionally, wafer-level packaging is an efficient process that simultaneously packages a plurality of dies, thereby reducing costs and increasing throughput.

Packaged microelectronic devices such as those described above are used in cellphones, pagers, personal digital assistants, computers, and many other electronic products. To meet the demand for smaller electronic products, there is a continuing drive to increase the performance of packaged microelectronic devices, while at the same time reducing the height and the surface area or “footprint” of such devices on printed circuit boards. Reducing the size of microelectronic devices, however, becomes more difficult as the performance increases because higher performance typically means more integrated circuitry and bond-pads, resulting in larger ball-grid arrays and thus larger footprints. One technique for increasing the density of microelectronic devices within a given footprint is to stack one device on top of another.

FIG. 1 schematically illustrates a first microelectronic device 10 stacked on top of a second microelectronic device 20 in a wire-bonded, stacked-die arrangement. The first microelectronic device 10 includes a die 12 having an integrated circuit 14 and a plurality of bond-pads 16 electrically coupled to the integrated circuit 14. The first microelectronic device 10 further includes a redistribution layer 18 having a plurality of first pads 11 electrically coupled to corresponding bond-pads 16. The second microelectronic device 20 similarly includes a die 22 having an integrated circuit 24 and a plurality of bond-pads 26 electrically coupled to the integrated circuit 24. The second microelectronic device 20 further includes a redistribution layer 28 having a plurality of second pads 21 electrically coupled to corresponding bond-pads 26. A plurality of wire-bonds 13 extend from the first pads 11 to corresponding second pads 21 to electrically couple the first microelectronic device 10 to the second microelectronic device 20.

The second pads 21 on the second microelectronic device 20 are positioned outside of the first microelectronic device 10 to facilitate wire-bonding. As mentioned above, wire-bonding can be a complex and expensive process.

Accordingly, it may not be feasible to form wire-bonds for the high-density, fine-pitch arrays of some high performance devices. Moreover, positioning the second pads 21 outside of the first microelectronic device 10 to accommodate the wire-bonds 13 undesirably increases the footprint of the stacked-die arrangement.

### BRIEF DESCRIPTION OF THE DRAWINGS

FIG. 1 schematically illustrates a first microelectronic device attached to a second microelectronic device in a wire-bonded, stacked-die arrangement in accordance with the prior art.

FIGS. 2A-2C illustrate various stages in a method of forming a plurality of microelectronic devices in accordance with one embodiment of the invention.

FIG. 2A is a schematic side cross-sectional view of a microfeature workpiece.

FIG. 2B is a schematic side cross-sectional view of the microfeature workpiece after forming a plurality of conductive mating structures.

FIG. 2C is a schematic side cross-sectional view of the microfeature workpiece after removing the resist.

FIG. 3 is a schematic side cross-sectional view of a microfeature workpiece in accordance with another embodiment of the invention.

FIG. 4A is a schematic side cross-sectional view of a plurality of stacked microelectronic devices in accordance with one embodiment of the invention.

FIG. 4B is a schematic side cross-sectional view of the stacked microelectronic devices of FIG. 4A after reflow.

FIGS. 5A-5E are top cross-sectional views of a plurality of first and second conductive mating structures in accordance with different embodiments of the invention.

FIG. 6 is a schematic side cross-sectional view of a plurality of upper microelectronic devices stacked on top of corresponding lower microelectronic devices in accordance with another embodiment of the invention.

FIG. 7 is a schematic side cross-sectional view of an upper microelectronic device stacked on top of a lower microelectronic device in accordance with another embodiment of the invention.

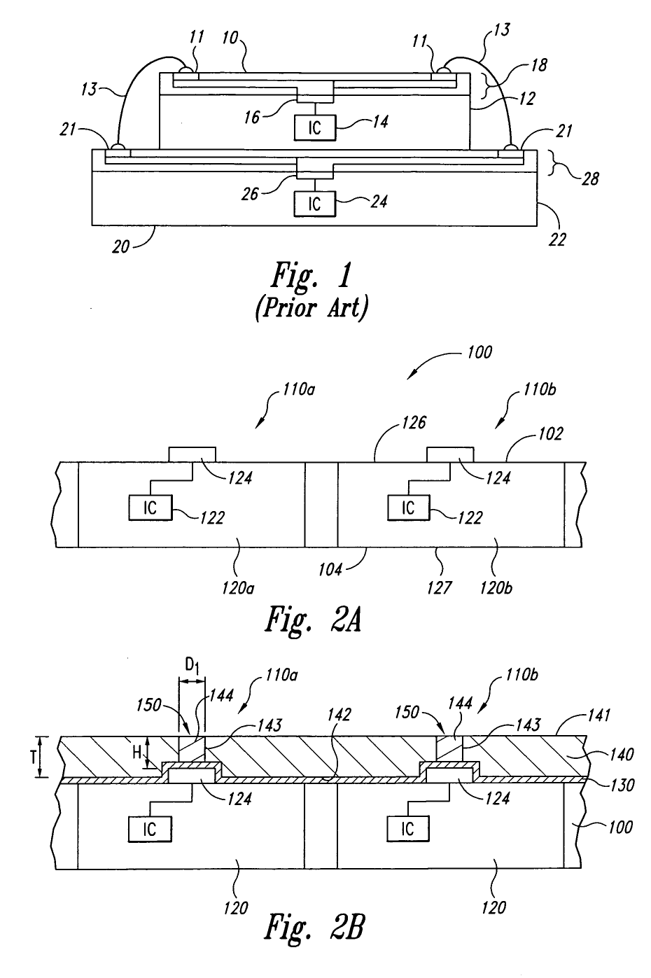

### DETAILED DESCRIPTION

A. Overview

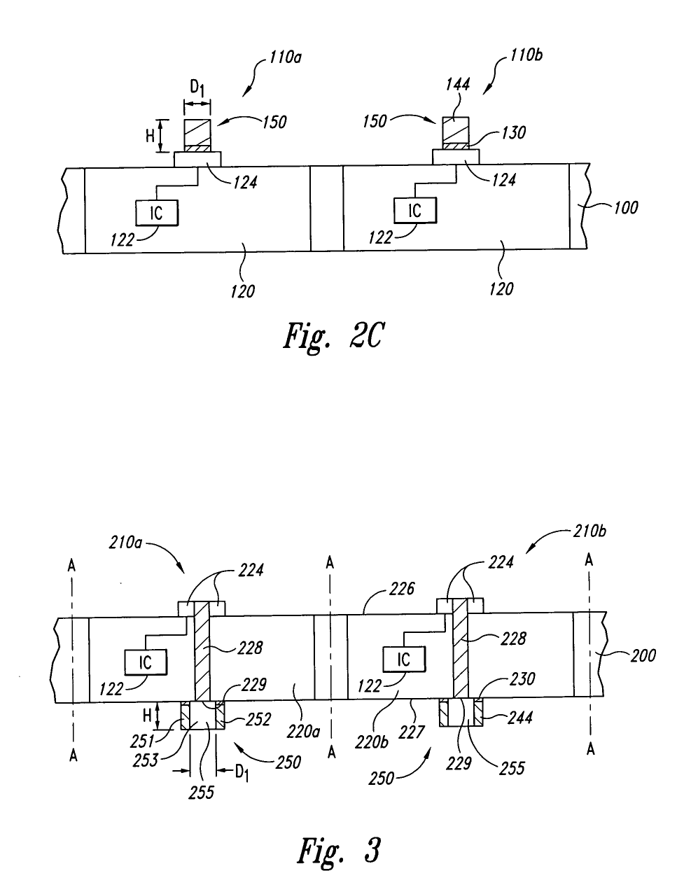

The present invention is directed toward microelectronic devices with conductive complementary structures, microfeature workpieces including microelectronic devices with conductive complementary structures, and methods of manufacturing the microelectronic devices and the microfeature workpieces. The term “microfeature workpiece” is used throughout to include substrates in or on which microelectronic devices, micromechanical devices, data storage elements, and other features are fabricated. For example, microfeature workpieces can be semiconductor wafers, glass substrates, insulated substrates, or many other types of substrates. Several specific details of the invention are set forth in the following description and in FIGS. 2A-7 to provide a thorough understanding of certain embodiments of the invention. One skilled in the art, however, will understand that the present invention may have additional embodiments, or that other embodiments of the invention may be practiced without several of the specific features explained in the following description.

Several aspects of the invention are directed to microfeature workpieces. In one embodiment, a microfeature workpiece includes a plurality of first microelectronic dies. The individual first dies have an integrated circuit, a plurality of pads electrically coupled to the integrated circuit, and a plurality of first conductive mating structures on corresponding pads. The first conductive mating structures project away from the first dies and are configured to interconnect with corresponding complementary second conductive mating structures on second dies which are to be mounted to corresponding first dies. The first conductive mating structures can have a circular, triangular, rectilinear, or other configuration. The first conductive mating structures can also have a receptacle to receive at least a portion of one of the second conductive mating structures.

Another aspect of the invention is directed to sets of stacked microelectronic devices. In one embodiment, a set includes a first microelectronic device having an integrated circuit, a plurality of first pads electrically coupled to the integrated circuit, and a plurality of first conductive mating structures on corresponding first pads. The set further includes a second microelectronic device having a plurality of second pads and a plurality of second conductive mating structures on corresponding second pads. The first and second microelectronic devices are positioned so that at least a portion of the second conductive mating structures are received by the first conductive mating structures. In one aspect of this embodiment, the first pads are first bond-pads and the second pads are second bond-pads. The first conductive mating structures can be coupled to the first bond-pads, and the second conductive mating structures can be coupled to the second bond-pads.

Another aspect of the invention is directed to methods of manufacturing stacked microelectronic devices. In one embodiment, a method includes providing a first microfeature workpiece having a plurality of first microelectronic dies with integrated circuits and first pads electrically coupled to the integrated circuits, and providing a second microelectronic workpiece having a plurality of second dies with integrated circuits and second pads electrically coupled to the integrated circuits. The method further includes forming a plurality of first conductive mating structures on corresponding first pads and forming a plurality of second conductive mating structures on corresponding second pads. The second conductive mating structures are configured to be received by corresponding first conductive mating structures. The method further includes positioning the first mating structure on at least one first die adjacent to a second mating structure on a corresponding second die. The first workpiece, for example, can be singulated and individual first dies could be mounted onto second dies before singulating the second workpiece. In another embodiment, the first mating structures can be placed adjacent to the second mating structures before singulating either workpiece such that the first dies are coupled to corresponding second dies at the wafer level.

B. Embodiments of Methods for Forming Microelectronic Devices on Microfeature Workpieces

FIGS. 2A-2C illustrate various stages in a method of forming a plurality of microelectronic devices in accordance with one embodiment of the invention. FIG. 2A, more specifically, is a schematic side cross-sectional view of a microfeature workpiece 100 having a first surface 102, a second surface 104 opposite the first surface 102, and a plurality of microelectronic devices 110 (two of which are shown and identified individually as 110a-b). The microelectronic devices 110 include a plurality of microelectronic dies 120 (identified individually as 120a-b) formed in an array on the microfeature workpiece 100. The microelectronic dies 120 include an integrated circuit 122 (shown schematically), a plurality of bond-pads 124 (only one shown on each die 120) electrically coupled to the integrated circuit 122, a first side 126, and a second side 127 opposite the first side 126. After forming the microelectronic dies 120, conductive mating structures are formed on the bond-pads 124 before cutting the workpiece 100 to singulate the dies 120.

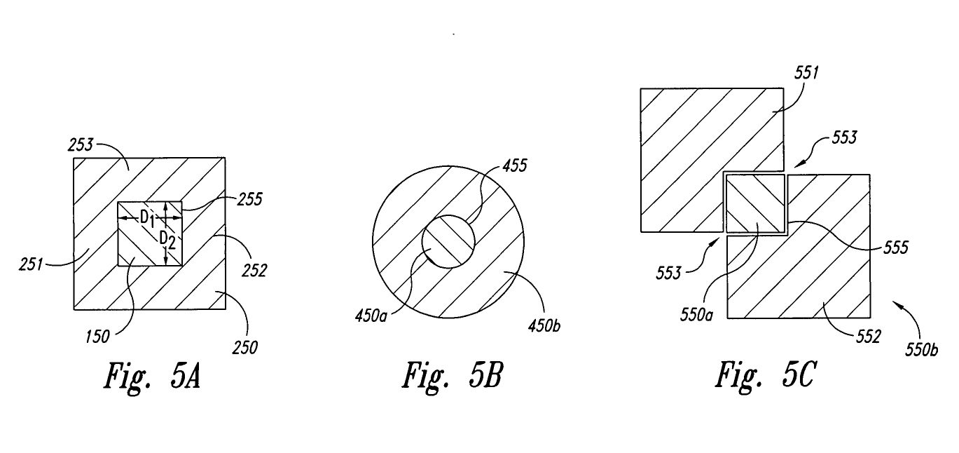

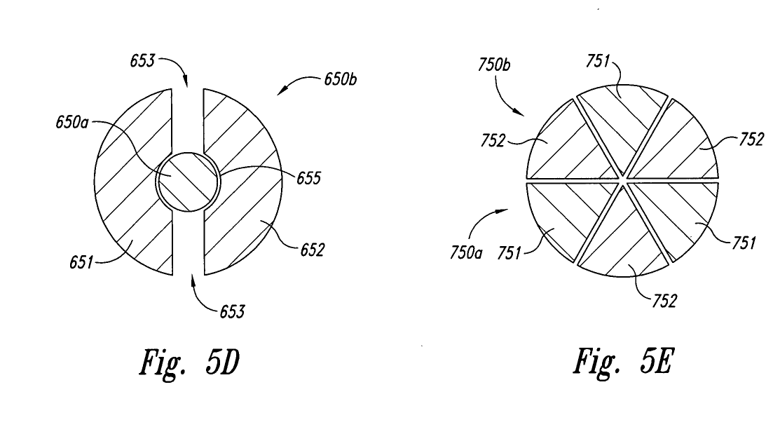

FIG. 2B is a schematic side cross-sectional view of the microfeature workpiece 100 after forming a plurality of conductive mating structures 150 on the workpiece 100. The mating structures 150 can be formed using a patterned plating process in which a seed layer 130 of a conductive material is deposited across the first surface 102 of the microfeature workpiece 100, including the bond-pads 124 of the dies 120. The seed layer 130 can be deposited using physical vapor deposition (PVD), atomic layer deposition (ALD), or other suitable processes. After depositing the seed layer 130, a resist layer 140 is formed across the microfeature workpiece 100 using known processes. The resist layer 140 has a first surface 141 and a second surface 142 opposite the first surface 141. In one aspect of this embodiment, the resist layer 140 has a thickness T from the first surface 141 to the second surface 142 of between approximately 25 microns and approximately 150 microns. In other embodiments, the thickness T can be less than 25 microns or greater than 150 microns. The resist layer 140 is patterned and developed to form a plurality of apertures 143 over the bond-pads 124. The shape and configuration of the apertures 143 correspond to the shape and configuration of the conductive mating structures 150. For example, in the illustrated embodiment, the apertures 143 have a rectangular configuration; however, in other embodiments, the apertures 143 can have a circular, triangular, or other configuration, as described below with reference to FIGS. 5A-5E. In any of these embodiments, the apertures 143 extend between the first surface 141 of the resist layer 140 and the seed layer 130 adjacent to the bond-pads 124.

After the apertures 143 are formed in the resist layer 140, a conductive material 144 is deposited into the apertures 143 and onto the exposed portions of the seed layer 130 to form the conductive mating structures 150. The conductive material 144 can be deposited onto the exposed portions of the seed layer 130 by electroplating, electroless plating, or other methods. The conductive material 144 can be solder or another suitable conductive material. In the illustrated embodiment, the conductive mating structures 150 have a height H and a width D₁. The size of the conductive mating structures 150 is precisely controlled by controlling the thickness T of the resist layer 140 and the size of the apertures 143.

FIG. 2C is a schematic side cross-sectional view of the microelectronic devices 110 after removing the resist layer 140 (FIG. 2B) to leave the mating structure 150 projecting from the bond-pads 124. The resist layer 140 can be stripped and the portion of the seed layer 130 extending between adjacent conductive mating structures 150 can be selectively etched to expose the first surface 102 of the microfeature workpiece 100. Accordingly, the microelectronic devices 110 can each include conductive mating structures 150 coupled to corresponding bond-pads 124. In the illustrated embodiment, each conductive mating structure 150 is sized and configured to be received within a corresponding conductive mating structure in a male-female configuration. In other embodiments, such as those described below with reference to FIG. 3 and 5A-7, the conductive mating structures can have other configurations.

FIG. 3 is a schematic side cross-sectional view of a microfeature workpiece 200 including a plurality of microelectronic devices 210 (identified individually as 210a-b) configured to be stacked on top of the microelectronic devices 110a-b by positioning the second workpiece 200 over the first workpiece 100 shown in FIG. 2C. The microelectronic devices 210 include a plurality of microelectronic dies 220 (identified individually as 220a-b) and a plurality of conductive mating structures 250 coupled to the dies 220. Several components of the microelectronic dies 220 can be similar to the microelectronic dies 120 described above with reference to FIGS. 2A-2C. For example, the microelectronic dies 220 include an integrated circuit 122 (shown schematically), a plurality of bond-pads 224 electrically coupled to the integrated circuit 122, a first surface 226, and a second surface 227 opposite the first surface 226.

The microelectronic dies 220 can further include a plurality of conductive links 228 extending between the first surface 226 and the second surface 227. The conductive links 228 shown in FIG. 3 are through-wafer interconnects electrically coupled to corresponding bond-pads 224. The ends of the conductive links 228 proximate to the second surface 227 define a plurality of pads 229. The through-wafer interconnect type conductive links 228 can be formed by laser drilling holes through the dies 220, depositing a dielectric layer along the sidewalls of the holes, spacer etching the dielectric layer, and then filling the holes with a metal. Suitable processes for forming the interconnects are disclosed in co-pending U.S. Application entitled Microelectronic Devices, Methods for Forming Vias in Microelectronic Devices, and Methods for Packaging Microelectronic Devices, filed on [______] (Perkins Coie Docket No. 10829-8742US00). In other embodiments, the microelectronic dies 220 may not include conductive links 228, or, alternatively, the conductive links 228 may not extend through the bond-pads 224. In still other embodiments, the conductive links 228 can extend along the side of the dies 220 in the area between the dies.

In the illustrated embodiment, the conductive mating structures 250 have a rectangular configuration with an aperture 255. More specifically, the conductive mating structures 250 include a first wall 251, a second wall 252 opposite the first wall 251, a third wall 253, and a fourth wall (not shown) opposite the third wall 253. The first wall 251, the second wall 252, the third wall 253, and the fourth wall define the apertures 255, which have a width D₁ and a height H. Accordingly, the conductive mating structures 250 have female configurations and are sized to receive corresponding male conductive mating structures, such as the conductive mating structures 150 described above with reference to FIG. 2C. After forming the microelectronic devices 210, the microfeature workpiece 200 can be cut along lines A-A to singulate the devices 210.

C. Embodiments of Methods for Stacking Microelectronic Devices

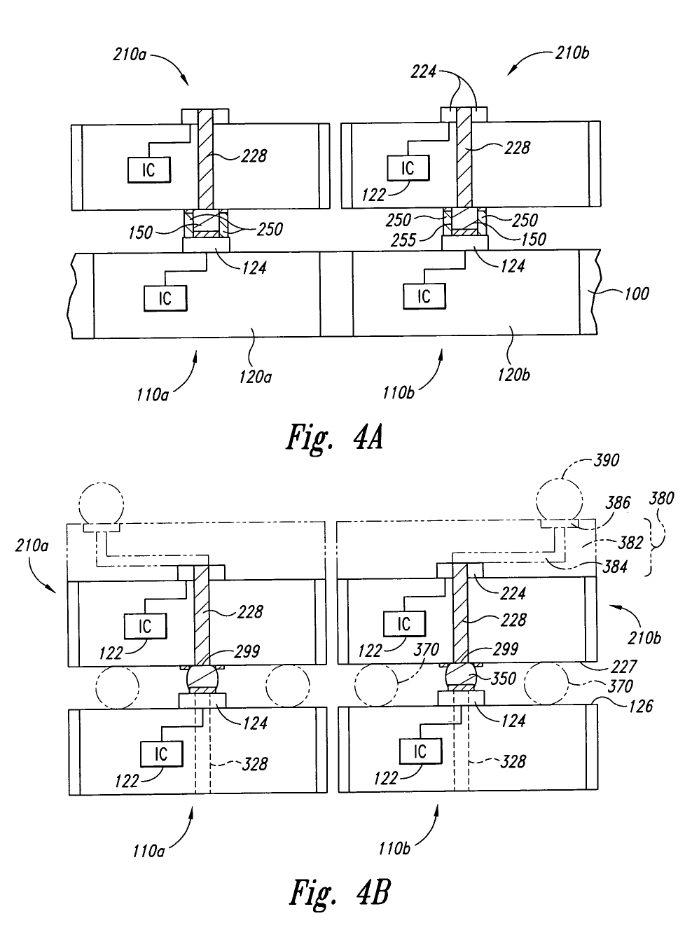

FIG. 4A is a schematic side cross-sectional view of the microelectronic devices 210 of FIG. 3 stacked on top of the corresponding microelectronic devices 110 of FIGS. 2A-2C in accordance with one embodiment of the invention. For ease of reference, the microelectronic devices 110 described above with reference to FIGS. 2A-2C and the microelectronic devices 210 described above with reference to FIG. 3 will hereafter be referred to as the lower microelectronic devices 110 and the upper microelectronic devices 210, respectively. Moreover, the conductive mating structures 150 and 250 will hereafter be referred to as the first conductive mating structures 150 and the second conductive mating structures 250, respectively. The lower and upper microelectronic devices 110 and 210 can be individually tested before stacking to determine which devices 110 and 210 function properly. After singulation, properly functioning upper microelectronic devices 210 can be stacked on corresponding lower microelectronic devices 110. More specifically, the first conductive mating structures 150 are inserted into the apertures 255 of the second conductive mating structures 250. The first conductive mating structures 150 can contact the corresponding second conductive mating structures 250. In other embodiments, the upper microelectronic devices 210 can be stacked on the lower microelectronic devices 110 before the microfeature workpiece 200 (FIG. 3) is cut to singulate the devices 210. In these embodiments, the microfeature workpieces 100 and 200 can be subsequently cut to singulate the stacked devices 110 and 210.

An advantage of the illustrated microelectronic devices 110 and 210 is that the first and second conductive mating structures 150 and 250 properly align the stacked lower and upper microelectronic devices 110 and 210. A further advantage of the illustrated devices 110 and 210 is that the first and second conductive mating structures 150 and 250 combine the stacking and aligning processes into one step. Yet another advantage of the illustrated microelectronic devices 110 and 210 is that the first and second conductive mating structures 150 and 250 can fix the distance between the devices 110 and 210.

FIG. 4B is a schematic side cross-sectional view of the lower and upper microelectronic devices 110 and 210 after reflowing the first and second conductive mating structures 150 and 250 (FIG. 4A). After stacking, the lower and upper microelectronic devices 110 and 210 can be heated to reflow the first and second conductive mating structures 150 and 250. The heat causes the first and second conductive mating structures 150 and 250 to reflow and form corresponding conductive couplers 350, which can have a generally ball-like configuration. The conductive couplers 350 are coupled to corresponding pads 299 and bond-pads 124 to electrically couple the lower microelectronic devices 110 to the upper microelectronic devices 210. Accordingly, the integrated circuits 122 of the lower microelectronic devices 110 are electrically coupled to the bond-pads 224 of the upper microelectronic devices 210. After reflowing the first and second conductive mating structures 150 and 250, the microfeature workpiece 100 (FIG. 4A) can be singulated to separate the stacked microelectronic devices 110 and 210.

In other embodiments, the stacked microelectronic devices 110 and 210 can include a plurality of spacers 370 (shown in broken lines) attached to the first side 126 of the lower microelectronic devices 110 and the second surface 227 of the upper microelectronic devices 210 to strengthen the stacked package and/or seal the conductive couplers 350 in a protected environment. In additional embodiments, the lower microelectronic devices 110 can include a plurality of conductive links 328 (shown in broken lines) similar to the conductive links 228 of the upper microelectronic devices 210. In other embodiments, the microfeature workpiece 100 can also be singulated before stacking the lower and upper microelectronic devices 110 and 210 and/or before reflowing the first and second conductive mating structures 150 and 250.

In additional embodiments, the upper microelectronic devices 210 can further include a redistribution layer 380 (shown in broken lines). The redistribution layer 380 can include a dielectric layer 382 (shown in broken lines), a plurality of conductive lines 384 (shown schematically) coupled to corresponding bond-pads 224, a plurality of pads 386 (shown schematically) at the end of corresponding conductive lines 384, and a plurality of electrical couplers 390 coupled to corresponding pads 386. The electrical couplers 390 can be solder balls arranged in arrays on the redistribution layer 380 and configured for attachment to a substrate such as a printed circuit board. Alternatively, a plurality of conductive mating structures can be formed on the pads 386 of the redistribution layer 380 for attachment to corresponding conductive mating structures on a substrate or microelectronic device.

One feature of the microelectronic devices 110 and 210 of the illustrated embodiment is that the size and location of the conductive mating structures 150 and 250 can be precisely controlled. One advantage of this feature is that the pitch between adjacent conductive couplers (which are formed after reflowing the conductive mating structures) on a microelectronic device can be reduced. For example, adjacent conductive couplers can have a pitch of approximately 100 microns or less. The ability to reduce the pitch between adjacent conductive couplers allows manufacturers to reduce the pitch between corresponding bond-pads, which increases the performance and reduces the footprint of the microelectronic device. Another advantage of the microelectronic devices 110 and 210 is that the devices can have a similar size and still be stacked on top of each other. Stacking microelectronic devices increases the capacity and/or the performance within a given area or footprint on a circuit board. In prior art stacked microelectronic devices, the lower devices had a larger size than the upper devices so that pads on the lower devices would be outboard the upper devices for wire bonding.

D. Embodiments of Different Configurations of Conductive Mating Structures

FIGS. 5A-5E are top cross-sectional views of a plurality of first and second conductive mating structures in accordance with different embodiments of the invention. FIG. 5A, more specifically, is a top cross-sectional view of one of the first conductive mating structures 150 and one of the second conductive mating structures 250 described above with reference to FIGS. 2-4B. In this embodiment, the first and second conductive mating structures 150 and 250 have generally rectangular configurations. The aperture 255 in the second conductive mating structure 250 is sized and configured to receive the first conductive mating structure 150. More specifically, the width D₁ and the length D₂ of the first conductive mating structure 150 are at least approximately equal to the width D₁ and the length D₂ of the aperture 255 in the second conductive mating structure 250.

FIG. 5B is a cross-sectional top view of a first conductive mating structure 450a and a second conductive mating structure 450b, each having a generally circular configuration in accordance with another embodiment of the invention. The second conductive mating structure 450b includes an aperture 455 sized and configured to receive the first conductive mating structure 450a. The mating structures 450a and 450b are not limited to being circular, but rather can be any curved shape (e.g., elliptical, oval, etc.).

FIG. 5C is a cross-sectional top view of a first conductive mating structure 550a and a second conductive mating structure 550b in accordance with another embodiment of the invention. The first conductive mating structure 550a has a generally rectangular configuration. The second conductive mating structure 550b includes a first portion 551 and a second portion 552 spaced apart from the first portion 551 by a gap 553. The first and second portions 551 and 552 define a void 555 sized and configured to receive the first conductive mating structure 550a.

FIG. 5D is a cross-sectional top view of a first conductive mating structure 650a and a second conductive mating structure 650b in accordance with another embodiment of the invention. The first conductive mating structure 650a has a generally circular configuration. The second conductive mating structure 650b includes a first portion 651 and a second portion 652 spaced apart from the first portion 651 by a gap 653. The first and second portions 650a-b define a void 655 sized and configured to receive the first conductive mating structure 650a.

FIG. 5E is a cross-sectional top view of a first conductive mating structure 750a and a second conductive mating structure 750b in accordance with another embodiment of the invention. The first conductive mating structure 750a includes a plurality of portions 751 spaced apart from each other by a series of gaps. The second conductive mating structure 750b similarly includes a plurality of portions 752 spaced apart from each other by a series of gaps. The gaps between the portions 752 of the second conductive mating structure 750b are sized and configured to receive the portions 751 of the first conductive mating structure 750a. In additional embodiments, the first and second conductive mating structures can have other configurations.

One feature of the embodiments illustrated in FIGS. 5C-5E is that the second conductive mating structures have a gap between separate portions of each structure. An advantage of this feature is that when the first and second conductive mating structures are engaged and reflowed, the gap allows gases to escape during reflow to prevent voids in the resulting conductive coupler. These mating structures are expected to provide superior performance because voids can have a detrimental effect on the conductivity and the strength of the conductive couplers.

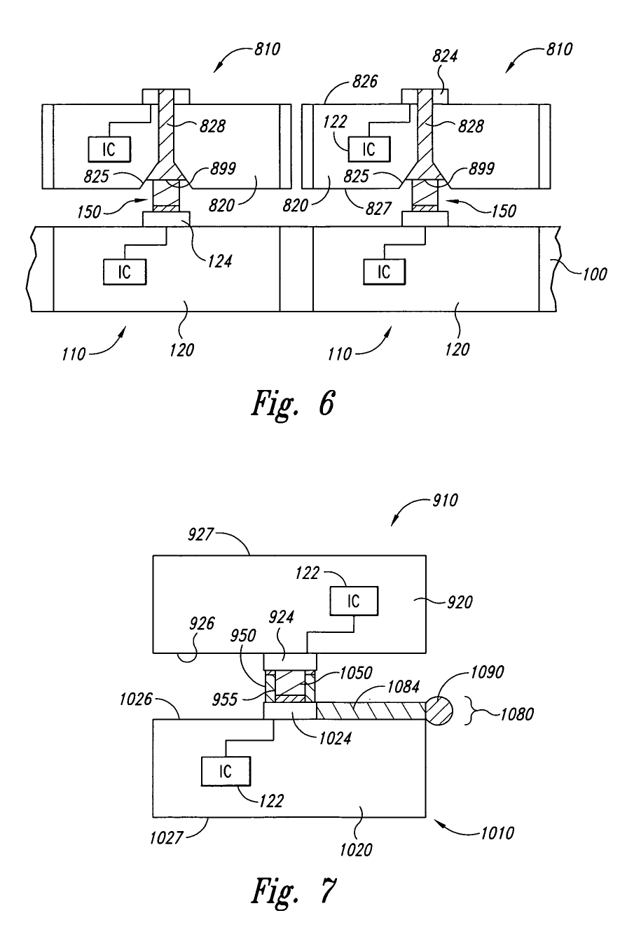

FIG. 6 is a schematic side cross-sectional view of a plurality of upper microelectronic devices 810 stacked on top of corresponding lower microelectronic devices 110 in accordance with another embodiment of the invention. The upper microelectronic devices 810 are generally similar to the microelectronic devices 210 described above with reference to FIG. 3. For example, the upper microelectronic devices 810 include a microelectronic die 820 having an integrated circuit 122 (shown schematically), a plurality of bond-pads 824 electrically coupled to the integrated circuit 122, a first surface 826, a second surface 827 opposite the first surface 826, and a plurality of conductive links 828 electrically coupled to corresponding bond-pads 824. The upper microelectronic devices 810 further include a plurality of apertures 825 in the second surface 827 that expose the ends of corresponding conductive links 828. In the illustrated embodiment, the exposed ends of the conductive links 828 define a plurality of pads 899 that are recessed from the second surface 827. The apertures 825 can be beveled to center conductive mating structures 150 of the lower microelectronic devices 110 on corresponding pads 899. The conductive mating structures 150 can be subsequently reflowed to bond the lower and upper microelectronic devices 110 and 810.

One feature of the upper microelectronic devices 810 of the illustrated embodiment is that the second surface 827 of the devices 810 is generally flat and the apertures 825 are beveled. An advantage of this feature is that the flat second surface 827 allows misaligned conductive mating structure 150 to slide laterally along the second surface 827, and the beveled apertures 825 automatically receive and center the conductive mating structures 150.

FIG. 7 is a schematic side cross-sectional view of an upper microelectronic device 910 stacked on top of a lower microelectronic device 1010 in accordance with another embodiment of the invention. The upper microelectronic device 910 can be generally similar to the microelectronic device 110 described above with reference to FIGS. 2A-2C. For example, the upper microelectronic device 910 includes a microelectronic die 920 having an integrated circuit 122 (shown schematically), a plurality of bond-pads 924 (only one shown) electrically coupled to the integrated circuit 122, a first surface 926, and a second surface 927 opposite the first surface 926. The upper microelectronic device 910 further includes a plurality of first conductive mating structures 950 (only one shown) on corresponding bond-pads 924. The first conductive mating structures 950 have a female configuration with an aperture 955 sized and configured to receive a complementary conductive mating structure.

The lower microelectronic device 1010 also includes a microelectronic die 1020 having an integrated circuit 122 (shown schematically), a plurality of bond-pads 1024 electrically coupled to the integrated circuit 122, a first surface 1026, and a second surface 1027 opposite the first surface 1026. The lower microelectronic device 1010 further includes a plurality of second conductive mating structures 1050 (only one shown) on corresponding bond-pads 1024. The second conductive mating structures 1050 have a male configuration and are sized to be received in the aperture 955 of corresponding first conductive mating structures 950. The lower microelectronic device 1010 further includes a redistribution layer 1080 having a plurality of conductive lines 1084 (only one shown) electrically coupled to corresponding bond-pads 1024 and a plurality of electrical couplers 1090 (only one shown) electrically coupled to corresponding conductive lines 1084. The redistribution layer 1080 can also include dielectric material (not shown).

From the foregoing, it will be appreciated that specific embodiments of the invention have been described herein for purposes of illustration but that various modifications may be made without deviating from the spirit and scope of the invention. Accordingly, the invention is not limited except as by the appended claims.

1-34. (canceled)

35. A method of forming a microfeature workpiece, the method comprising:
constructing a plurality of microelectronic dies on a microfeature workpiece, wherein individual microelectronic dies have an integrated circuit and a plurality of bond-pads electrically coupled to the integrated circuit; and
forming a plurality of first conductive mating structures on corresponding bond-pads, the first conductive mating structures projecting away from the workpiece and being configured to mate with a plurality of second conductive mating structures of other microelectronic devices in a stacked die arrangement.

36. The method of claim 35 wherein forming the first conductive mating structures comprises forming structures with a generally circular, triangular, or rectangular configuration.

37. The method of claim 35 wherein forming the first conductive mating structures comprises:
depositing a seed layer onto the bond-pads; and
plating a conductive material onto the seed layer.

38. The method of claim 35 wherein forming the first conductive mating structures comprises forming the first conductive mating structures with solder material.

39. The method of claim 35 wherein forming the first conductive mating structures comprises forming the first conductive mating structures such that the first conductive mating structures project away from the bond-pads at an angle generally normal to the microfeature workpiece.

40. The method of claim 35 wherein forming the first conductive mating structures comprises forming the first conductive mating structures with a male configuration projecting away from the bond-pads.

41. The method of claim 35 wherein forming the first conductive mating structures comprises forming the first conductive mating structures with a female configuration, the first conductive structures having an opening to receive corresponding second conductive mating structures.

42. A method of manufacturing stacked microelectronic devices, the method comprising:
constructing a plurality of first microelectronic devices on a first microfeature workpiece, the first microelectronic devices including a microelectronic die with an integrated circuit and a plurality of first pads electrically coupled to the integrated circuit;
forming a plurality of first conductive mating structures on or at least proximate to corresponding first pads;
manufacturing a plurality of second microelectronic devices on a second microfeature workpiece, the second microelectronic devices including a plurality of second pads;
forming a plurality of second conductive mating structures on or at least proximate to corresponding second pads, the second conductive mating structures being configured to mate with corresponding first conductive mating structures; and
positioning at least one of the first microelectronic devices on the second microfeature workpiece so that the first conductive mating structures of the at least one first microelectronic device mate with the second conductive mating structures of the corresponding second microelectronic device.

43. The method of claim 42 wherein forming the first conductive mating structures comprises forming the first conductive mating structures with generally circular, triangular, or rectangular configurations.

44. The method of claim 42 wherein forming the first conductive mating structures comprises forming the first conductive mating structures with male or female configurations.

45. The method of claim 42 wherein forming the first conductive mating structures comprises:
depositing a seed layer onto the first pads; and
plating a conductive material onto the seed layer.

46. The method of claim 42, further comprising reflowing the first and second conductive mating structures of the at least one first microelectronic device and the corresponding second microelectronic device to form a plurality of conductive couplers.

47. The method of claim 42 wherein:
the first microelectronic devices have a first side and a second side opposite the first side;
the first pads comprise a plurality of bond-pads on the first side of the first microelectronic devices; and
forming the first conductive mating structures comprises forming the first conductive mating structures on the bond-pads on the first side of the first microelectronic devices.

48. The method of claim 42 wherein:
the first microelectronic devices include a first side, a second side opposite the first side, a plurality of bond-pads on and/or in the first side, and a plurality of conductive links extending from the first side to the second side;
the conductive links have a plurality of ends defining the first pads on the second side of the first microelectronic devices; and
forming the first conductive mating structures comprises forming the first conductive mating structures on the first pads on the second side of the first microelectronic devices.

49. The method of claim 42, further comprising cutting the first microfeature workpiece to singulate the first microelectronic devices before positioning at least one of the first microelectronic devices.

50. The method of claim 42 wherein:
forming the first conductive mating structures comprises forming the first conductive mating structures such that the first conductive mating structures project away from the first microfeature workpiece; and
forming the second conductive mating structures comprises forming the second conductive mating structures such that the second conductive mating structures project away from the second microfeature workpiece.

51. A method of stacking microelectronic devices, the method comprising:
constructing a first microelectronic device with an integrated circuit and a plurality of first pads electrically coupled to the integrated circuit;
forming a plurality of first conductive mating structures on or at least proximate to corresponding first pads, the first conductive mating structures projecting away from the first microelectronic device;
providing a second microelectronic device with a plurality of second pads;
forming a plurality of second conductive mating structures on or at least proximate to corresponding second pads, the second conductive mating structures projecting away from the second microelectronic device and being configured to mate with the first conductive mating structures; and
aligning the first and second microelectronic devices by interfacing the first and second conductive mating structures.

52. The method of claim 51 wherein forming the first conductive mating structures comprises forming the first conductive mating structures with a generally circular, triangular, or rectangular configuration.

53. The method of claim 51 wherein forming the first conductive mating structures comprises forming the first conductive mating structures with a male or female configuration.

54. The method of claim 51 wherein forming the first conductive mating structures comprises:
depositing a seed layer onto the first pads; and
plating a conductive material onto the seed layer.

55. The method of claim 51, further comprising reflowing the first and second conductive mating structures to form a plurality of conductive couplers.

56. A method for coupling a first microelectronic device with a plurality of first pads to a second microelectronic device with a plurality of second pads, the method comprising:
forming a plurality of first conductive complementary structures on or at least proximate to corresponding first pads of the first microelectronic device, the first conductive complementary structures projecting away from the first microelectronic device;
forming a plurality of second conductive complementary structures on or at least proximate to corresponding second pads of the second microelectronic device, the second conductive complementary structures projecting away from the second microelectronic device and being configured to mate with the first conductive complementary structures;
mating the first conductive complementary structures with the second conductive complementary structures; and
reflowing the first and second conductive complementary structures to form a plurality of conductive couplers between corresponding first and second pads.

57. The method of claim 56 wherein forming the first conductive complementary structures comprises forming the first conductive complementary structures with a generally circular, triangular, or rectangular configuration.

58. The method of claim 56 wherein forming the first conductive complementary structures comprises forming the first conductive complementary structures with a male or female configuration.

59. The method of claim 56 wherein forming the first conductive complementary structures comprises:
depositing a seed layer onto the first pads; and
plating a conductive material onto the seed layer.
